(19) United States
(12) Patent Application Publication
(10) Pub. No.: US 2016/0108515 A1
(43) Pub. Date: Apr. 21, 2016

(54) METHOD FOR FILLING VIAS AND SUBSTRATE-VIA FILLING VACUUM PROCESSING SYSTEM

(71) Applicant: EVATEC ADVANCED TECHNOLOGIES AG, Balzers (LI)

(72) Inventors: MOHAMED ELGHAZZALI, Feldkirch (AT); Jurgen WEICHART, Balzers (LI)

(73) Assignee: EVATEC ADVANCED TECHNOLOGIES AG, Balzers (LI)

(21) Appl. No.: 14/892,268

(22) PCT Filed: May 23, 2014
(86) PCT No.: PCT/EP2014/060620

§ 371 Date: Nov. 19, 2015

Related U.S. Application Data
(60) Provisional application No. 61/826,592, filed on May 23, 2013.

(51) Int. Cl. C23C 14/34; C23C 14/02; C23F 4/00; C23C 14/04; H01J 37/34; H01J 37/32; C23C 14/06; C23C 14/58

(52) U.S. Cl. CPC C23C 14/34; C23C 14/3407; C23C 14/0623; C23C 14/022; C23C 14/5873; C23C 14/5826; C23C 14/046; H01J 37/3429; H01J 37/3476; H01J 37/32431; C23F 4/00

(57) ABSTRACT

Vias of at least approx. 1:1 aspect ratio in substrates are filled with material which exhibits a thermally driven amorphous/crystalline phase change. This is performed within a vacuum process chamber. During a first timespan the material is sputter-deposited by DC sputtering from a material target. In a subsequent timespan a void, which may remain in the via as material covered by the addressed sputtering, is opened by etching performed with the help of an inductively coupled plasma generated by an Rf driven electric coil and applying to the substrate with the via an Rf bias.

The present invention relates to the art of filling vias with an aspect ratio of at least approx. 1:1 in a substrate. The vias may have a depth in the small submicron as below 40 nm.

From the US 2007/0074968 it is known to deposit films onto high aspect ratio submicron featured semiconductor wafers by making use of ionized physical vapor deposition (iPVD) and etching.

Similarly, the U.S. Pat. No. 5,800,688 proposes to fill submicron high aspect ratio features on very large scale integrated semiconductor devices making use of iPVD.

The U.S. Pat. No. 5,178,739 addresses the deposition of material uniformly into high aspect ratio holes or trenches.

US 2003/0034244 addresses metallization of via and trenched structures on semiconductor wafers making use of sequentially applied deposition and etching steps.

The U.S. Pat. No. 6,719,886 addresses that ionized physical vapor deposition is a process which has particular utility in filling and lining high aspect ratio structures on silicon wafers. The principle of iPVD is explained.

Attention is also drawn on EP 0 782 172, U.S. Pat. No. 6,287,435 and U.S. Pat. No. 6,417,626.

Out of the generic art of filling high aspect submicron vias of high aspect ratio generically with a material as addressed above the present invention is more specifically directed on filling such vias with an aspect ratio of approx. 1:1 with a chalcogenide glass material which exhibits a thermally driven amorphous/crystalline phase change.

This technique is specifically addressed in the article DOI 10.1007/s00399-012-7463-8 “Nanoscale gap-filling for phase change material by pulsed deposition and inductively coupled plasma etching”, W. C. Ren et al., Applied Physics, Springer. The article departs from the recognition that gap-filling of phase-change material has become a critical module in the fabrication process of phase-change random access memory (PCRAM) as the device continues to scale down to 45 nm and below. It appears from the article that void-free gap filling with phase-change material on 30 nm vias with aspect ratios of 1:1 by a two-cycle deposition/etching/deposition process (DED) is achieved. As a specific example of chalcogenide glass material which exhibits a thermally driven amorphous/crystalline phase-change, Ge₂Sb₂Te₅ (GST) is applied. For material deposition DC magnetron sputtering is applied, DC being in fact pulsed DC. For etching, soft etching is applied with the help of an inductively coupled plasma (ICP). The PVD material deposition step and the etching step are performed without vacuum break between the deposition and the etching process steps.

It is an object of the present invention to improve the method as addressed in the W. C. Ren et al. article and to provide a substrate via filling vacuum processing system to operate such improved method.

This object is achieved by a method of filling vias with an aspect ratio of at least approx. 1:1 within a substrate and thereby manufacturing substrates comprising vias filled with a material. The material is a chalcogenide glass material which exhibits a thermally driven amorphous/crystalline phase-change out of the group of following materials:

GeSbTe, AgInSbTe, InSe, SbSe, SbTe, InSbTe, GeSbSe, GeSbTeSe, AgInSbSeTe,

Thereby the material is especially GeSbTe (GST).

### DEFINITION

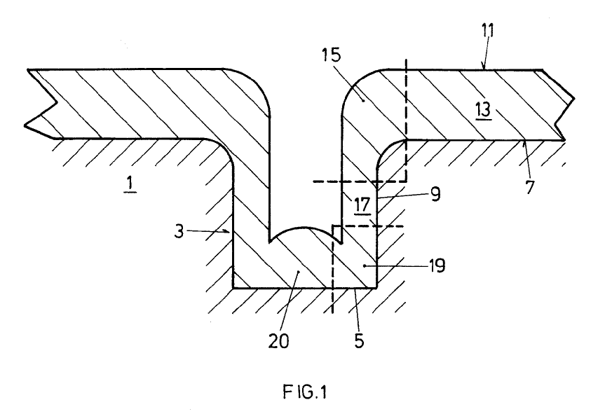

When discussing or claiming material deposition in vias as addressed, it is important to clarify what specific areas of a via and of the respective covering is addressed. These areas of via and respective covering shall be defined in context with FIG. 1. This definition accords with the definition as customarily applied by the skilled artisan in this art and as applied also in the addressed article of W. C. Ren et al.

FIG. 1 schematically shows a cross-section through a via of approx. 1:1 aspect ratio which has been material-covered, yet not being filled.

In a substrate 1 a via 3 comprises a via bottom 5 and a via top 7. In fact, the via top 7 is the part of the surface of substrate 1, wherein via 3 is worked.

Via sidewalls 9 link via bottom 5 to via top 7. The via covering 11 may be subdivided in top covering 13, which transits into sidewall top covering 15 of sidewall covering 17. Sidewall top covering 15, by which top covering 13 transits into sidewall covering 17 is approx. addressed by dashed line in FIG. 1.

Sidewall covering 17 transits via bottom sidewall covering 19 into via bottom covering 20.

Via bottom sidewall covering 19, by which via sidewall covering 17 transits into via bottom covering 20 is also shown qualitatively by dashed line in FIG. 1.

Turning back to the method, by which the object as addressed above is resolved, such method comprises:
a) sputter-depositing by DC sputtering, which is continuous DC sputtering or pulsed DC sputtering the material from a target arrangement upon an area of at least one substrate comprising at least one via. Thereby, a covering of the addressed material is established on the via top, the via sidewalls and the via bottom. The covering includes a via top covering. The addressed sputter depositing is further performed to an extent to leave a void in the covered via, whereby the addressed void is open towards the surrounding of the via top covering.

In a subsequent step b) the addressed void is enlarged towards the surrounding of the via top covering by etching with the help of an inductively coupled plasma. Thus, the void which remains after step a) is wedge-like opened and enlarged towards the surface of the via top covering 13 as of FIG. 1.

Subsequent to the addressed step b) a step c) is performed, in which the addressed material is sputter-deposited by DC sputtering upon the addressed area. This is performed to an extent so as to either complete the filling of the via by the addressed material at least from the via bottom to the via top or to again leave a void in the covered via which void is open towards the surrounding of the via top covering.

In the case that by the addressed step c) a void is left in the covered via which is open towards the surrounding of the via top covering, step b), i.e. the etching step, and step c), i.e. the sputter-depositing step, are repeated. The steps a) to step c) are performed in one common vacuum process chamber, so that not only no vacuum break occurs, but additionally only one processing chamber becomes necessary without transporting the substrates in vacuum from one processing chamber to the other. Transporting the substrate from a deposition chamber to an etching chamber and back to a deposition chamber several times has the significant disadvantage of complicated transport arrangements, possibly with loadlocks, and especially bears the danger of contaminating the substrate as by particles. Additionally, such forth and back transport significantly slows down the production rate, i.e. the throughput.

In a good embodiment of the method according to the invention, which may be combined with any of the subsequently addressed method embodiments, unless in contradiction, DC sputtering which may include continuous or pulsed DC sputtering and is in fact magnetron sputtering, is performed in the addressed steps a) and c) without applying a bias signal to the substrate by a settable biasing source operationally connected to the substrate. This means that no external biasing source is operationally connected via a substrate holder to the substrate.

In a good embodiment of the method according to the invention, which may be combined with any of the preaddressed and subsequently addressed method-embodiments, unless in contradiction, igniting the inductively coupled plasma as applied in step b) is performed by a plasma of sputter-depositing as exploited in step a) and/or step c). Inversely, the inductively coupled plasma of step b) ignites the sputtering plasma in step c). Thereby, it must be emphasized that it is perfectly clear to the skilled artisan that sputtering necessitates a plasma.

Thereby, not only the addressed process steps are performed without transport in one common vacuum process chamber, but additionally, in the addressed vacuum process chamber, a plasma is continuously maintained during the addressed steps, as one plasma of one step ignites the plasma of the subsequent step.

In a good embodiment of the method according to the invention, which may be combined with any of the preaddressed method embodiments and such embodiments still to be addressed, unless in contradiction, the substrate is a silicon wafer.

In a good embodiment of the method according to the invention, which may be combined with any of the preaddressed embodiments and such embodiments still to be addressed, unless in contradiction, the method further comprises providing the substrate in the one common vacuum process chamber along a substrate plate. The target arrangement, which comprises one or more than one targets, is provided along a substantially plane or dome-shaped cover part of the common vacuum process chamber. The addressed target arrangement faces the at least one substrate. The cover part, either plane or dome-shaped, transits into lateral walls of the common vacuum process chamber along a substantially circular area. Thus, the lateral walls of the common vacuum process chamber are realized, at least in the addressed transit area, by a cylindrical wall. With respect to a central axis of the addressed circular area this area thus defines for an inner radius Rᵢ and an outer Rₒ. The circular area resides at least substantially in a plane, named transiting plane, which is at least substantially parallel to the addressed substrate plane.

A spacing d between the substrate plan and the transiting plane, with respect to the inner radius Rᵢ of the substantially circular area, is selected to fulfil:

0.7≦Rᵢ/d≦1.6.

In a today practiced good embodiment there is selected

1≦Rᵢ/d≦1.6.

By this embodiment a medium-throw setup of the one common vacuum process chamber is realized. Such medium-throw setup results in a narrow angular distribution of the sputtered off material compared to a more common low-distance or low-throw sputtering setup. Thereby, it should be considered that the radius Rᵢ substantially defines for the respective maximum extent of the target arrangement within the one common vacuum process chamber. The vacuum process chamber is customarily not tailored larger than necessary and is primarily governed by the extent of a target arrangement to be provided, besides of the extent of substrates to be treated. Thus, the addressed radius Rᵢ of the circular area at least approx. defines for the extent of the target arrangement as seen from the substrate. Additionally, such medium-throw setup allows the implementation of the inductively coupled plasma between the target arrangement and the substrate.

In a good embodiment of the method according to the invention, which may be combined with any of the preaddressed method embodiments and such embodiments still to be addressed, unless in contradiction, the total pressure in the common vacuum process chamber during sputter-depositing of step a) and during sputter-depositing of step c) is selected to be higher than a total pressure selected in the one common vacuum process chamber during the etching of step b) by a factor of at least 2 to 30, preferably by a factor of at least 10.

In a further good embodiment of the method according to the invention, which may be combined with any of the preaddressed method embodiments and such embodiments still to be addressed, unless in contradiction, the target arrangement is selected to comprise more than one target. By this and respective control of the more than one of the addressed targets it becomes possible to optimally control sputter-deposition distribution. Thereby, in a good embodiment of the just addressed embodiment the addressed more than one targets are provided of different materials and the stoichiometry of the sputter-deposited material is controlled by individually controlling the sputtering rates of the addressed more than one targets.

In a further good embodiment of the method according to the invention, which may be combined with any of the preaddressed method embodiments and such embodiments still to be addressed, unless in contradiction, at least one target of the target arrangement, which may comprise one or more than one target, is tilted with respect to a substrate plane along which the one or more than one substrate reside for processing.

In a further good embodiment of the method according to the invention, which may be combined with any of the preaddressed method embodiments and such embodiments still to be addressed, unless in contradiction, the total pressure p_{b} applied in step b) is selected to be

10⁻⁴ mbar≦p_{b}≦2·10⁻³ mbar.

In a good embodiment there is selected

10⁻⁴ mbar≦p_{b}≦10⁻³ mbar,

and further in a good embodiment as today practiced

5·10⁻⁴ mbar≦p_{b}≦2·10⁻³ mbar.

In a further good embodiment of the method according to the invention, which may be combined with any of the preaddressed method embodiments and such embodiments still to be addressed, unless in contradiction, the method comprises performing step a) and step c) at a total pressure pₐ, p_{c} respectively in the common vacuum process chamber of

5·10⁻³ mbar≦pₐ≦5·10⁻² mbar

5·10⁻³ mbar≦p_{c}≦5·10⁻² mbar, or of

10⁻² mbar≦pₐ≦10⁻¹ mbar,

10⁻² mbar≦p_{c}≦10⁻¹ mbar,

as practiced today.

In a further good embodiment of the method according to the invention, which may be combined with any of the preaddressed method embodiments and such embodiments still to be addressed, unless in contradiction, the inductively coupled plasma is generated by means of an electric coil arrangement with at least one electric coil wound around at least a part of the inner volume of said one common vacuum process chamber and preferably operating the coil with an electric current at a frequency fᵢ for which there is valid:

400 kHz≦fᵢ≦27 MHz,

thereby as practiced today of

400 kHz≦fᵢ≦450 kHz.

In a further good embodiment of the method according to the invention, which may be combined with any of the preaddressed method embodiments and such embodiments still to be addressed, unless in contradiction, the inductively coupled plasma is generated by means of an electric coil arrangement with at least one electric coil wound around at least a part of the inner volume of the one common vacuum process chamber, whereby the addressed electric coil is also operated during at least one of the steps a) and c) for controlling thickness distribution of the sputter-deposited covering.

In a further good embodiment of the method according to the invention, which may be combined with any of the preaddressed method embodiments and such embodiments still to be addressed, unless in contradiction, Rf biasing is applied at a voltage u_{bias} for which there is valid:

35 V≦u_{bias}≦100 V.

In a further good embodiment of the method according to the invention, which may be combined with any of the preaddressed method embodiments and such embodiments still to be addressed, unless in contradiction, before performing step a) there is applied a seed layer in the addressed via. Preferably the thickness of such seed layer is selected to be between 0.5 nm and 5 nm, both limits included.

By such a seed, also called wetting layer, the risk of overhangs being formed by the sputter-depositing steps a) is further reduced. The addressed seed layer avoids the formation of such overhangs and helps to distribute the material. The sputter-deposited material coagulates with a high contact angle upon such seed layer resulting in a reduced adhesion and in a reduced risk of void formation inside the via. By such seed layer the adhesion of sputter-deposited material is thus improved and completely filling the via is facilitated.

In a further good embodiment of the method according to the invention, which may be combined with any of such preaddressed method embodiments and such embodiments still to be addressed, unless in contradiction, the seed layer is of W or of Ta₂O₅. Thereby, preferably W is applied by sputtering and Ta₂O₅ by reactive sputtering. These seed layer materials are preferably applied in combination with GeSbTe as covering material.

In a further good embodiment of an embodiment in which a seed layer is applied as was addressed above, the seed layer is applied within the addressed one common vacuum process chamber or in a separate vacuum process chamber.

In a further good embodiment of the method according to the invention, which may be combined with any of the preaddressed method embodiments and such embodiments still to be addressed, unless in contradiction, the substrate is rotated or oscillated during at least one of the addressed steps a), b) c).

So as to operate the method according to the invention in all of the embodiment addressed above, there is proposed a substrate via-filling vacuum system which comprises a vacuum process chamber with at least one substrate holder therein. The vacuum process chamber comprises a sputtering target arrangement comprising one or more than one targets, the material of the one target or the materials of the more than one targets in combination being of all elements of one material out of the following material group:

GeSbTe, AgInSbTe, InSe, SbSe, SbTe, InSbTe, GeSbSe, GeSbTeSe, AgInSbSeTe,

thereby especially of GeSbTe (GST). Thus and e.g. with an eye on GST, in the case of more than one target one target may be e.g. of Ge, one other target e.g. of Sb and a third target then of Te.

The process chamber further comprises an electric coil arrangement with at least one electric coil which is wound around at least a part of the inner volume of the vacuum process chamber. The system further comprises
a first Rf power supply arrangement
a second Rf power supply arrangement
a continuous or pulsed DC power supply arrangement
a process control unit.

The process control unit is thereby adapted to control
establishing of a supply operational connection of the DC power supply arrangement to the sputtering target arrangement for a first predetermined timespan,

at the end of the first timespan
disabling of the supply operational connection between the DC power supply arrangement and the sputtering source arrangement and
establishing of a supply operational connection of the first Rf power supply arrangement to the electric coil arrangement and establishing of a bias operational connection of the second Rf power supply arrangement to the substrate holder.

In other words, the substrate via filling vacuum system according to the invention has, at one common vacuum process chamber, a sputtering source arrangement for sputtering or co-sputtering the desired chalcogenide glass material. It further comprises an electric coil arrangement by which an inductively coupled plasma may be generated in at least a part of the inner volume of the vacuum process chamber and comprises further a first Rf power supply to supply the coil arrangement, a second Rf power supply arrangement to bias the substrate support and a continuous or pulsed DC power supply arrangement to supply the target arrangement. By means of the process control unit during a first timespan the system is controlled to establish DC sputtering. Subsequent to the first timespan and during a second predetermined timespan the process control unit disables sputtering and enables operation of the inductively coupled plasma, thereby the operation of the substrate holder at an Rf electric bias potential.

In a good embodiment of the system according to the invention, which may be combined with any system embodiment still to be addressed, unless in contradiction, during establishing by the process control unit the supply operational connection of the DC power supply arrangement to the sputtering target arrangement and thus during the first predetermined timespan, no signal supply source is operationally connected to the substrate holder. Thus, no external biasing source is connected to the addressed substrate holder, especially not an Rf biasing source.

In a good embodiment of the system according to the invention, which may be combined with any system embodiment addressed and still to be addressed, unless in contradiction, the process control unit is adapted to control the second predetermined timespan so as to initiate as the first predetermined timespan terminates. Thus, the process control unit is in fact adapted to control sputtering timespan, the first predetermined timespan, to continuously transit into the “etching” timespan, the second predetermined timespan, in which Rf bias and inductively coupled plasma are operated.

In a good embodiment of the system according to the invention, which may be combined with any preaddressed system embodiment and system embodiments still to be addressed, unless in contradiction, the sputtering target arrangement comprises more than one target and the process control unit is adapted to individually control the sputter rate of said more than one targets.

The sputter rate may thereby be controlled preferably by respectively adjusting the electric power applied to the respective targets, i.e. the continuous or pulsed DC power supplied and/or by the strength of respective magnetron magnet fields.

In a good embodiment of the just addressed system embodiment at least some of the more than one targets are of different materials.

In a good embodiment of the system according to the invention, which may be combined with any preaddressed system embodiment and system embodiments still to be addressed, unless in contradiction, a medium throw setup of the one process chamber is realized as was discussed in context with the method according to the invention in that the substrate holder is tailored to define a substrate plane within the vacuum process chamber. The vacuum process chamber comprises a substantially plane or a dome-shaped cover part facing the substrate plane. The sputtering target arrangement is mounted along the addressed cover part. The cover part transits into lateral walls of the vacuum process chamber along a substantially circular area about a central axis of the vacuum process chamber. The circular areas defines, with respect to the addressed central axis, an inner radius Rᵢ and an outer radius Rₐ. The addressed circular area further resides substantially in a plane which is called “transiting plane” and which is substantially parallel to the substrate plane. So as to establish the addressed medium-throw setup a spacing d between the substrate plane and the transiting plane with respect to the inner radius Rᵢ of the substantially circular area is selected to be

0.7≦Rᵢ/d≦1.6

or

1≦Rᵢ/d≦1.6.

In a good embodiment of the system according to the invention, which may be combined with any preaddressed system embodiment and system embodiments still to be addressed, unless in contradiction, the process control unit is adapted to control pressure in the vacuum process chamber during the second predetermined timespan to be smaller than the pressure in the vacuum process chamber during the first timespan by a factor of at least 2 to 30, or of at least 10.

In a good embodiment of the system according to the invention, which may be combined with any preaddressed system embodiment and system embodiments still to be addressed, unless in contradiction, the substrate holder defines for a substrate plane and the or at least one target of the sputtering target arrangement is tilted with respect to an axis perpendicular to the substrate plane by an angle of less than 90°.

In a further good embodiment of the system according to the invention, which may be combined with any preaddressed system embodiment and system embodiments still to be addressed, unless in contradiction, the electric coil arrangement comprises at least one electric coil and further comprises a tubular body of a dielectric material, preferably of a ceramic material. The outer surface of the tubular body faces the at least one electric coil and the inner surface of the tubular body faces the part of the inner volume of the vacuum process chamber about which the at least one electric coil is wound. Thus, there is provided a tubular body between the at least one electric coil and the addressed part of the inner volume of the process chamber.

In a good embodiment of the just addressed embodiment the vacuum process chamber has an encapsulating wall and the tubular body is a part of the encapsulating wall. Thus, the addressed at least one electric coil does not reside within the inner volume of the vacuum process chamber, but is separate therefrom by the addressed tubular body. Thereby, the addressed at least one electric coil may be integrated into the encapsulating wall of the vacuum process chamber at that locus where the tubular body as well forms part of the addressed encapsulating wall or the addressed electric coil may reside separate from the encapsulating wall, i.e. in the surrounding of the addressed vacuum process chamber.

In a further good embodiment of the system which comprises the addressed tubular body there is provided a slotted tubular shield along the inner surface of the tubular body, whereby the slots or slits of the addressed shield, a multitude thereof being provided, are preferably directed in a direction at least substantially parallel to a central axis of the tubular shield.

In a further good embodiment of the system according to the invention, which may be combined with any system embodiment already addressed and system embodiment still to be addressed, the first Rf power supply source is adapted to generate an Rf power at a frequency fᵢ of

400 kHz≦fᵢ≦27 MHz,

thereby preferably of

400 kHz≦fᵢ≦450 kHz.

In a further good embodiment of the system according to the invention, which may be combined with any system embodiment already addressed and still to be addressed, unless in contradiction, the second Rf power supply arrangement is adapted to generate an Rf voltage u_{bias} of:

35 V≦u_{bias}≦100 V.

In a further good embodiment of the system according to the invention, which may be combined with any system embodiment already addressed and still to be addressed, unless in contradiction, the process control unit is adapted to maintain an operational connection of the electric coil arrangement to an Rf power supply arrangement during the first predetermined timespan.

In a further good embodiment of the system according to the invention, which may be combined with any system embodiment already addressed and still to be addressed, unless in contradiction, the system further comprises a sputtering source for a seed layer material, preferably of W or of Ta₂O₅. The further sputtering source is provided either within the vacuum process chamber or in a further process chamber remote from the addressed vacuum process chamber.

In a further good embodiment of the system according to the invention, which may be combined with any system embodiment already addressed and still to be addressed, unless in contradiction, the vacuum process chamber is substantially symmetric with respect to a central axis. The at least one electric coil is provided with the coil axis coaxial to the addressed central axis or intersecting said central axis.

The invention shall now be further explained and exemplified with the help of figures. The figures show:

FIG. 1 as already described shows schematically a cross-section through a via in a substrate and the different parts of a covering within the via;

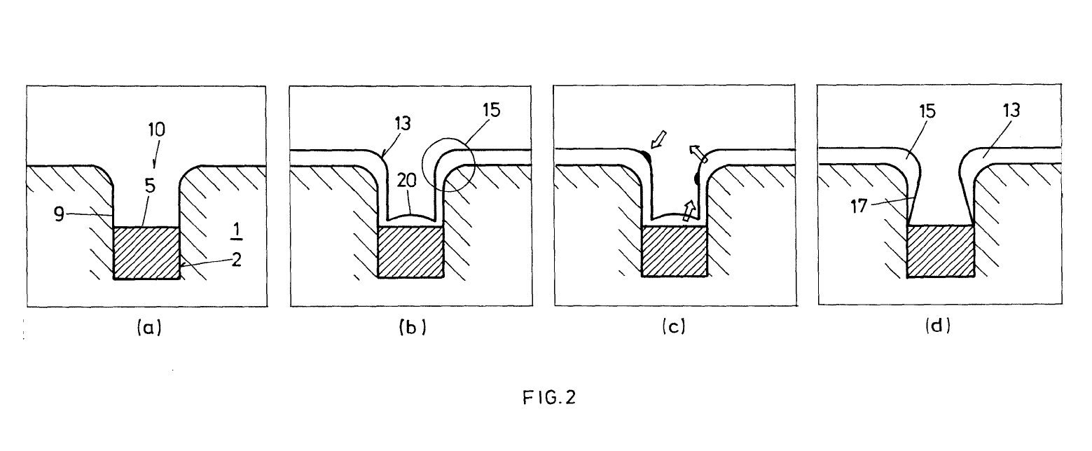

FIG. 2(a) schematically and in a cross-sectional representation, a via in a substrate having an aspect ratio of at least approx. 1:1;

FIG. 2(b) schematically and qualitatively, departing from a via according to FIG. 2(a), the profile of a material PVD covering of the via;

FIG. 2(c) departing from a covered via as of FIG. 2(b), regular Rf etching and re-deposition of etched covering material;

FIG. 2(d) departing from the representation of FIG. 2(c), schematically and qualitatively, the resulting covering profile after etching and redeposition as schematically shown in FIG. 2(c);

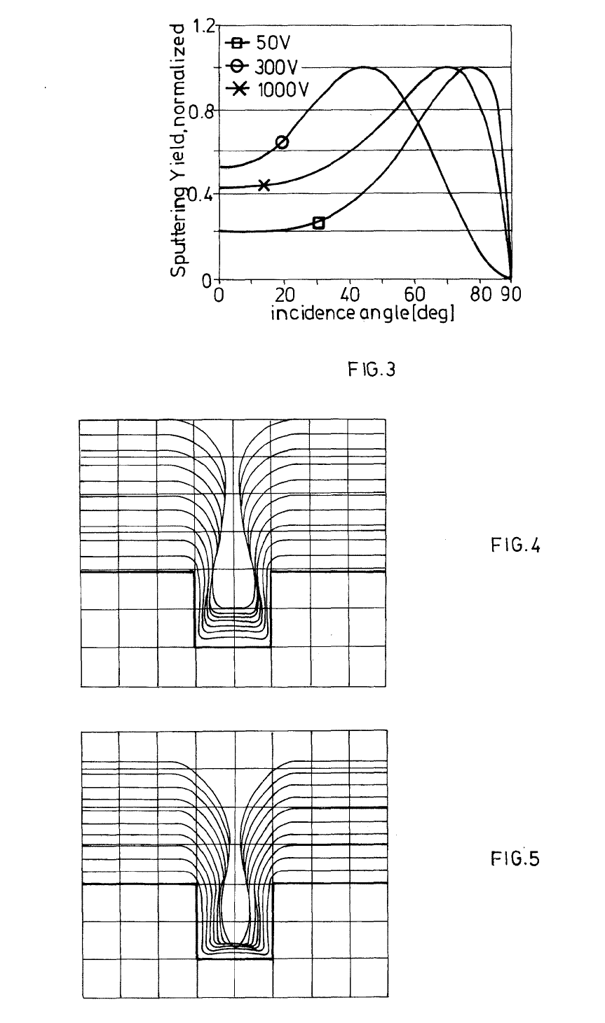

FIG. 3 the normalized sputtering yield as a function of angle of incidence of argon ions at ion energies of 50 V, 300 V and 1000 V;

FIG. 4 a simulated profile of a via covered by sputter-deposition, whereby the via has an aspect ratio of 1:1;

FIG. 5 departing from a simulated profile of the via covering according to FIG. 4, the resulting simulated profile after 20% etching and redeposition for an Ar ion energy of 1000 V;

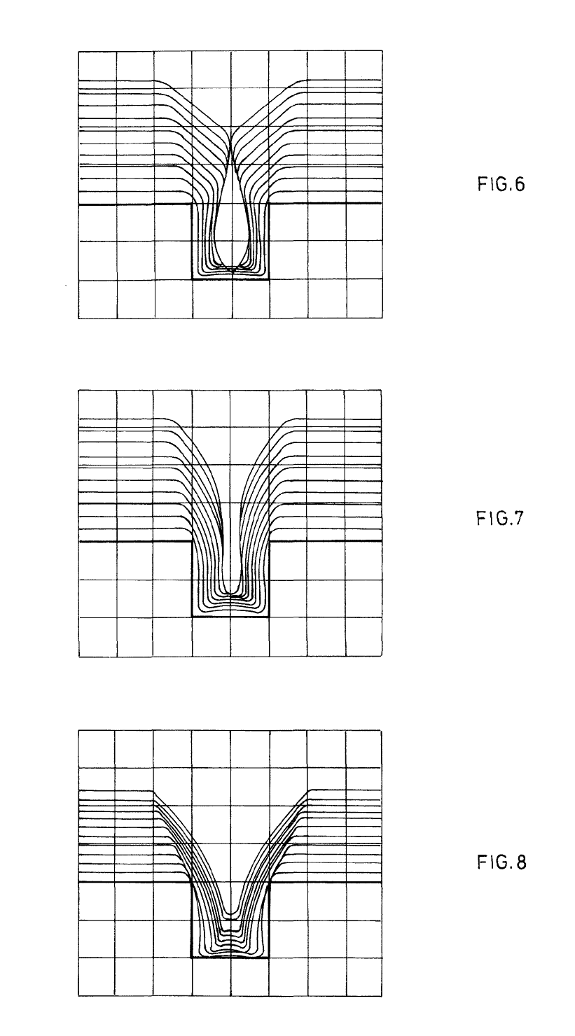

FIG. 6 departing from a simulated covering profile as of FIG. 4, the resulting simulated covering profile after 20% etching and redeposition for an Ar ion energy of 300 V;

FIG. 7 departing from a simulated covering profile as of FIG. 4, the resulting covering profile after 20% etching and redeposition for an Ar ion energy of 50 V. This profile is an example of a profile achieved by the method and accordingly the system of the invention;

FIG. 8 departing from a simulated covering profile as of FIG. 4, the profile achieved by 40% etching and redeposition for an Ar ion energy of 50 V. This profile is an example of an optimized covering profile as achieved during operation of the method and accordingly the system of the invention;

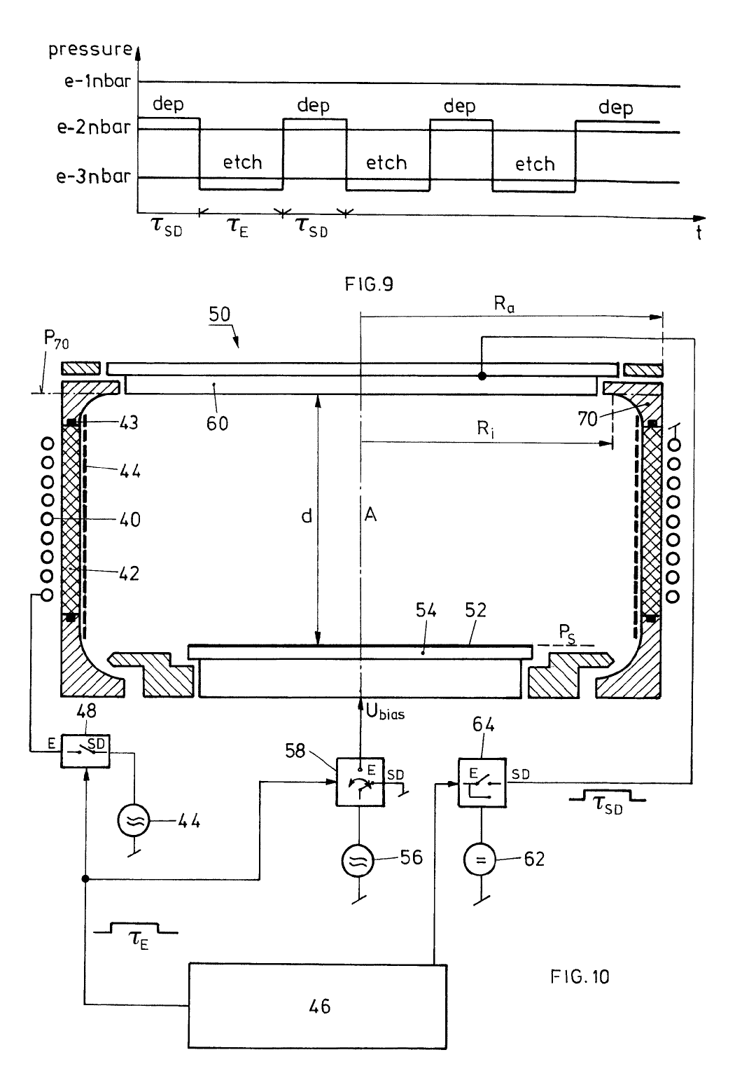

FIG. 9 over the time axis, the sequence of sputter-deposition and of etching by inductively coupled plasma (ICP) and the total pressure values which are applied during the respective sputter-deposition- and ICP etching-steps in a good example of the method and system of the invention;

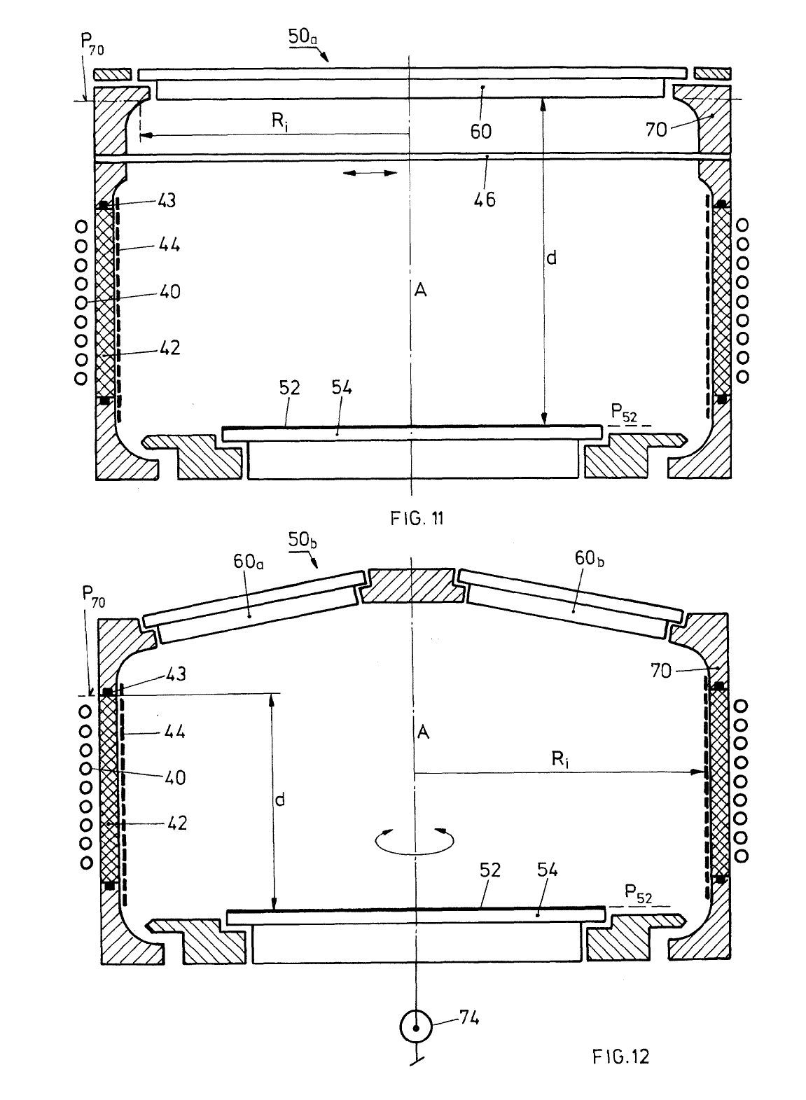

FIG. 10 schematically and simplified, the cross-section through a vacuum process chamber embodiment according to the system according to the invention and of additional system units provided to operate the addressed vacuum process chamber according to the method of the invention;

FIG. 11 a further embodiment of a vacuum process chamber which may be applied in the overall system as shown in FIG. 10, thereby resulting in a further embodiment of the system of the invention, operated according to the method of the invention;

FIG. 12 in a representation in analogy to the representation of FIGS. 10 and 11, a further embodiment of a vacuum process chamber as exploited by the present invention;

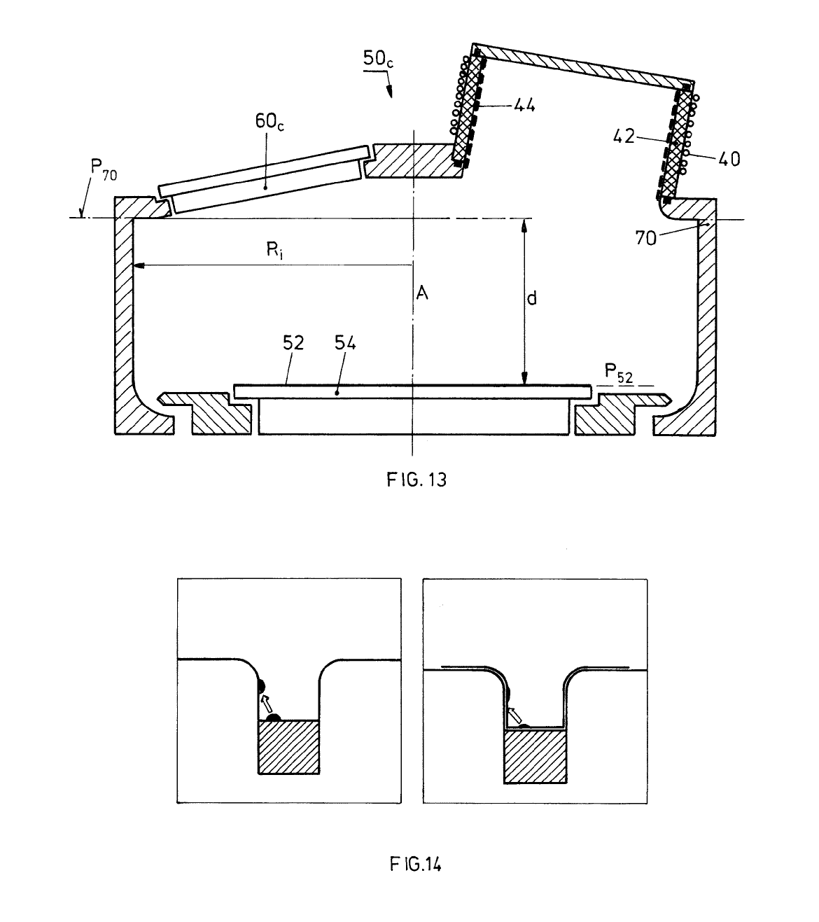

FIG. 13 still in a representation according to one of the FIGS. 10 to 12, a still further embodiment of a vacuum process chamber as exploited by the present invention;

FIG. 14 by means of a schematic representation, the effect of providing a seed layer—also called wetting layer—upon the via surfaces, especially with respect to contact angle. Left-hand representation without seed layer, right-hand representation with seed layer,

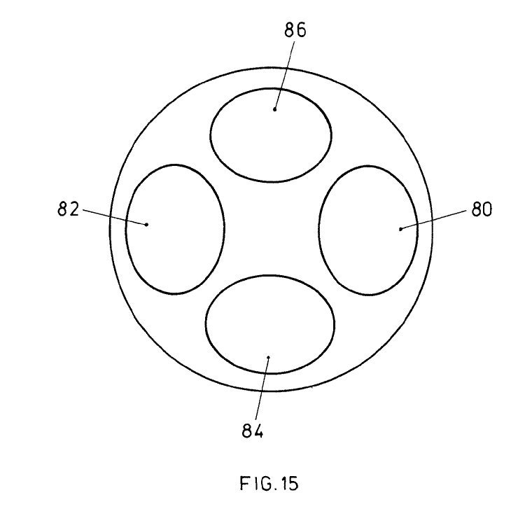

FIG. 15 most schematically and in top view, a system according to the present invention, wherein two targets are provided for material deposition, an ICP etch source as well as a sputtering source for seed layer material in one common vacuum process chamber. Substrates are subsequently treated by the respective sources as a batch of substrates.

Straight ahead deposition of chalcogenide glass material exhibiting a thermally driven amorphous/crystalline phase-change as of GeSbTe (GST) into vias with an aspect ratio 1:1 as of a via 10 in FIG. 2(a) results in overhanging material, especially in the sidewall top covering area 15 as illustrated in FIG. 2(b). The via depicted in FIG. 2 as an example is formed on one hand by via sidewalls 9 of a substrate or wafer 1, whereby the via bottom 5 is the top surface of an electrode inlay 2. Provision of an electrode inlay 2 within the original via of the substrate 1 is of no influence upon the present invention, besides of the fact that by means of the addressed electrode inlay 2 the remaining via 10 becomes a 1:1 aspect ratio via.

For properly and completely filling the via 10 with covering material it is necessary to remove such overhanging material.

One way to do such removing is to apply Rf bias on the substrate to be coated. As a substrate bias usually Rf bias of 13.56 MHz is applied. Thereby, there are two ways to apply Rf substrate bias: Either such Rf bias is permanently applied during deposition of the covering material or such Rf bias is applied intermittent to the material deposition step in a so-called dep-etch process step. It is this latter approach which is taken by the present invention.

Thereby, material—e.g. GST-deposition, is performed without bias, especially without Rf bias, during a first predetermined timespan. Subsequently an Rf bias etch step during a subsequent predetermined timespan is performed. This etching step is followed by a material deposition step. Usually, the first and the last steps, i.e. the deposition steps, are performed by PVD-sputtering and in between there is operated the addressed ICP etch step. The ICP etching step under Rf bias of the substrate may be performed by using a shutter between a target arrangement to perform the material deposition upon the substrate and the substrate, which technique is principally known as under-shutter etch mode.

It is customary to perform the etching step with Rf substrate bias under high voltages of several hundred Volts and at a relatively high pressure in the respective processing chamber in the range of 10⁻² mbar, which shows up to be disadvantageous. These high voltages lead to removal of the material from the via bottom covering 20 (see FIG. 2(b)) and to re-deposition of this removed material on the lower side of the sidewall top covering 15, so that, as a consequence, the overhang grows and makes the situation even worse. Also the relatively high pressure leads to scattering of the etched material, so that the overhang tends to grow also towards viatop covering 13. These effects are schematically shown in FIG. 2(c). As a result the bottom covering 20 may already be completely removed by etching and only the sidewall covering 17, the thickened via sidewall top covering 15 as well as via top covering 13 remain as schematically shown in FIG. 2(d).

The inventors of the present invention have found in simulation of etching on vias that low voltages in the range of 35 to 100 V of Rf biasing the substrate are optimal for properly removing overhanging covering material. Thus, they have found how to practice the etching in opposition of customary approaches. This is due to the fact that the sputter yield and thus, in etching, the etching yield is a function of the angle of incidence which depends on etching ion energy. This effect is plotted in FIG. 3 for argon etching ion energies of 50 V, 300 V and 1000 V. Additionally, a relatively low pressure is favorable to avoid back-scattering of etched material, sputtered off from the covering of the via, in the direction towards via surface.

FIG. 4 shows the simulation of a deposition or covering material profile in a 1:1 aspect ratio via, without etching, also called “back-sputtering”. Departing from such covering profile as of FIG. 4, FIGS. 5, 6 and 7 show the result of etching calculated if 20% of the covering as of FIG. 4 are etch-removed and partly re-deposited. The energy of the Ar ions is set to 1000 V (FIG. 5), 300 V (FIG. 6) and 50 V (FIG. 7). The profile as of FIG. 8 is achieved at 40% of the covering as of FIG. 4 removed and redeposited, by etching at an Ar ion energy of 50 V. Profiles as of FIG. 7 and especially as of FIG. 8 are realized by the method and system of the present invention, thereby providing for a top-enlarged void in the via, which allows in a subsequent sputter-deposition step, subsequent to the etching step, to deposit covering material down to the very bottom area of the voids. According to the invention a most efficient way of achieving such advantageous void profile in the already material-covered via is to apply a low pressure of below 10⁻³ mbar and to apply an inductively coupled plasma (ICP) for etching the previously sputter-deposited covering material.

As shown in the FIGS. 10 to 13, an inductive coil is arranged around a ceramic tubular body 42. The induction coil 40 is operated by an Rf source 44, whereby operational connection of the Rf source 44 to the induction coil 40 is controlled by a process control unit 46 and as schematically represented in FIG. 10 via a switching unit 48. The Rf supply source 44 for the inductive coil 40 is operated at a frequency between 400 kHz and 27 MHz (both limits included), in a today realized mode of operation, at a frequency of 400 to 450 kHz (both limits included). With the help of the Rf-operated inductive coil 40 a high-density inductively coupled plasma—ICP—is generated in the process chamber 50. Argon is used as a working gas to be ionized. The argon ions are accelerated to the substrate 52 by applying an Rf-bias to the substrate holder 54. According to FIG. 10 this is realized by means of an Rf biasing source 56. Enabling and disabling biasing of the substrate holder 54 is controlled by the process control unit 46, as schematically shown via controlling a switching unit 58. During the etching step the process control unit 46 establishes an operational connection of Rf source 44 to induction coil 40 and of Rf biasing source 56 to the substrate holder 54. Thereby, argon ions fed to the vacuum process chamber 50 are accelerated towards the substrate 52 by the applied Rf bias of low voltage, preferably in the range of 35 to 100 V (both limits included).

As further schematically shown in FIG. 10 a target 60 of material to be deposited into the via in substrate 52, e.g. of GST, is operated by a DC supply source 62 which supplies continuous or pulsed DC power. Enabling and disabling operational connection between the DC source 62 and target 60 is controlled by process control unit 46, as schematically shown via an enabling/disabling unit switch 64.

In the sputter deposition step, in which material is sputtered from target 60 and deposited upon substrate 52 and in the respective via, e.g. resulting in a covering profile as depicted in FIG. 4, the operational connection of the DC supply source 62 to target 60 is established during a sputter-deposition timespan τ_{SD} of predetermined length. During this timespan τ_{SD} the biasing source 56 is disabled with respect to operational connection to substrate holder 54, which latter is e.g. operated at a reference electric potential as of ground potential. The DC-supply source 62 is operatively connected to the target 60 and to the substrate holder 54. Sputtering is in fact operated without a dedicated biasing source being operatively connected to the substrate holder 54 and thus to the substrate 52.

During this sputter-deposition timespan τ_{SD} the induction coil 40 is operationally disconnected from Rf supply source 44, although it might be advantageous to operate the induction coil 40 also during the sputter-deposition step, i.e. during timespan τ_{SD}, to control deposition distribution of material sputtered off the target 60 upon the substrate 52.

It has to be noted that embodiments of processing chambers 50a, 50b, 50c as depicted in the FIGS. 11 to 13 may replace the process chamber 50 as of FIG. 10. Therefore, in the FIGS. 11 to 13 the additional units shown in FIG. 10 are not shown. In FIG. 10 the timespan of etching operation with the help of the inductively coupled plasma generated by operation of the induction coil 40 is addressed by τ_{E}.

The efficiency of the ICP concept to etch-remove overhanging material is per se known, and published in Appl. Phys. A, DOI 10.1007/s00339-012-7463-8 mentioned above. Thereby, as was addressed, the substrate was transported from a material deposition chamber to an ICP etching chamber and back to the deposition chamber several times. The disadvantage of such process flow is that many transport steps are involved without breaking the vacuum, which transport steps may easily contaminate the substrate or are prone to collect particles. The transport with repeated use of the same chamber as of the addressed article slows down overall processing and has therefore been recognized by the inventors of the present invention to be hardly a solution for industrial production.

According to the present invention the material deposition step or steps and the etching step or steps are performed in one common process chamber as evident from the FIGS. 10 to 13 with the help of the inductively coupled plasma.

As was addressed, the solution of completely filling vias with an aspect ratio substantially of 1:1 with chalcogenide glass material exhibiting a thermally driven amorphous/crystalline phase-change especially of GST is to combine the sputtering step or module for material deposition into the via on one hand with the low voltage ICP sputter-etching step or module working at a pressure of less than 10⁻³ mbar in a common process chamber, on the other hand thereby, in a good embodiment the vacuum processing chamber, wherein both sputter-deposition as well as ICP etching is performed, is dimensioned as a medium-throw setup chamber.

According to the chamber embodiment shown in the FIGS. 10 to 13 the substrate 52 or the substrate holder 54 define a substrate plane P₅₂.

The target arrangement of one target 60 or of more than one target 60ₐ, 60_{b}, e.g. as of FIG. 12, is arranged along a substantially plane cover part of the common vacuum process chamber 50, 50a, as of FIG. 10 or FIG. 11 or along a more dome-shaped cover part as of the embodiments according to the FIGS. 12 and 13.

The cover part, being plane or dome-shaped, transits into the lateral wall of the common vacuum process chamber along a substantially circular area as exemplified by area 70 in the FIGS. 10 to 13. The circular area 70 is thereby circular about a central axis A. The circular area 70 defines, as shown in FIG. 10 and with respect to the central axis A, an inner radius Rᵢ and an outer radius Rₐ. The circular areas 70 reside in a plane addressed in FIG. 10 by P₇₀ and called “transiting plane”. For constructing the vacuum process chamber 50, 50ₐ, 50_{b} and 50_{c} as a medium-throw setup chamber the spacing d between the substrate plane Pₛ and the transiting plane P₇₀, is selected to fulfil:

1≦Rᵢ/d≦1.6.

E.g. for the chamber embodiment of FIG. 10 and for a silicon wafer 52 of 300 mm, a target diameter of 400 to 480 mm this results in a spacing d which accords with a target to substrate spacing of 150 to 200 mm. Thus, by the target substrate distance d being similar to the sputter-target arrangement radius a medium-throw setup vacuum process chamber is realized. In the chamber embodiments as shown in the frame of the overall system the ceramic tubular body 42 is installed with vacuum O-ring sealings 43. The ceramic tube 42 is cooled by a circulating air flow (not shown). The inductive coil 40 is wound to apply the inductive coupling and is, in the embodiment shown, provided outside the wall or encapsulation of the vacuum process chamber.

As was addressed in context with FIG. 10 the Rf supply source 44 for the electric coil 40 is run at a radio frequency between 400 kHz and 27 MHz, thereby in a good embodiment, between 400 kHz and 450 kHz (all limits included).

Since especially by the sputter-deposition process a conductive layer material is produced, the ceramic tube 44 has to be protected. This is performed by a slotted shield 44 which has slots directed in axial direction with respect to the axis of the coil 42. By this it is prevented that a closed loop of conductive material is formed on the ceramic tube 42, which would shield the inductive coupling from the coil 42 into the vacuum process chambers 50 to 50_{c}.

The overall process of filling vias according to the invention consists of a number of n cycles, where n is in the range of 1 to 10. The first cycle consists of a deposition, an ICP etching and a deposition step. Subsequent cycles consist of an ICP etching and a deposition step. As was already addressed, the sputter-deposition step is performed by DC sputtering, which may include DC pulsed sputtering and is run at a higher pressure than the ICP etching step. This is shown in FIG. 9. For the ICP etching, i.e. during timespan τ_{E}, the ICP coil 40 and the Rf bias 56 are switched on. Sputter-deposition and ICP etching is performed in the same vacuum process chamber, which has the significant advantage that the overall process in fact is continuously active. As shown in FIG. 9 the step of etching is performed not only subsequent to the deposition step, but the etching step starts at the very end of the deposition step and vice versa. Thus, no intermittent time gap occurs between subsequent processing steps. Thereby, the plasma exploited for sputter-deposition during timespan τ_{SD} is exploited for igniting the inductively coupled plasma and vice versa. In other words the sputter-deposition discharge serves as ignition for the etch-plasma so that a direct transition from sputter-deposition step to etch-step is performed.

With an eye on FIG. 9 it has to be noted that the sputter-deposition steps during τ_{SD} need by no means be all of equal duration, which is also valid for the durations of more than one etching steps, τ_{E}.

As has been addressed in context with FIG. 10, it may be further advantageous to use the coil setup for the ICP in the etching step also in the sputter-deposition step, thereby possibly operated at a different power, so as to control the uniformity of material deposition on the substrate and via. In this case the coil 40 is also Rf operated during the sputter-deposition step as by supply source 44.

In many cases it may be an advantage to use a shutter 46 as schematically shown in the embodiment of FIG. 11, between the sputtering target arrangement with the target 60 and the back area of the inner volume of the vacuum process chamber 50 a, in which the inductively coupled etching plasma is operated. The shutter is closed during the etching step in order to protect the target 60 as of FIG. 11 and forms a closed environment for the ICP etching.

In the embodiment of FIG. 12 there are provided more than one target 60ₐ and 60_{b} arranged along a dome-shaped cover part of vacuum process the chamber 50_{b}. The targets are each significantly smaller than the substrate and are tilted with respect to the central axis A so as to improve uniform material deposition on the substrate 52. Thereby, the substrate holder 54 and thus the substrate 52 are in a good embodiment rotated as by a drive 74 about axis A. Such rotation of the substrate may also be provided especially in the embodiment according to FIG. 13, but also in the embodiment according to the FIGS. 10 and 11.

There are several advantages to use more than one sputtering source and thus more than one target:
Since some of the addressed chalcogenide glass materials have a high sputter rate, as especially GST, small and cost-effective targets can be used.
A multi-target setup also provides sputter-deposition at a low angle of incidence upon the substrate, which improves filling operation of the vias.
Installing more than one target, e.g. up to four, in the vacuum process chamber and e.g. along a dome-shaped covering part enables co-sputtering of the compounds or elements of the material finally to be deposited. Also multi-layers may be deposited. By individually controlling the addressed targets with respect to sputter rate the stoichiometry of the resulting covering material may be controlled and adjusted. Additionally, in some cases targets of that material which is to be deposited are not manufactured and it nevertheless becomes possible to sputter-deposit the desired material by making use of more than one target of different materials, in combination resulting in depositing the desired multi-compound material.
If in a more than one target arrangement shutters are necessary, such shutters can be made small, light-weight and easy to handle.

The induction coil 40 with the ceramic tubular body 42 and shield 44 may be implemented around the whole chamber diameter as in the embodiments of FIGS. 10, 11 and 12. In an alternative configuration as shown in FIG. 13 a small ICP source with coil 40, ceramic tube 42 and shield 44 is provided, offset from the axis A and inclined with respect to axis A and the substrate plane P₅₂. This makes such vacuum process chamber 50c highly compact and flexibly adaptable to different needs. The embodiment of FIG. 13 is of relatively low complexity and price and is especially suited for actual substrate sizes of 300 mm diameter.

For further reducing the risk that a void within the material covering of the via becomes closed towards the surrounding as e.g. shown in FIG. 6, which occurrence may prevent subsequent reopening such void towards a profile as shown in the FIG. 7 or 8, it may be highly advantageous to apply a thin layer upon the surface of the via before applying the first material sputter-deposition step. Such thin layer, a seed or wetting layer, avoids the formation of overhangs and helps to distribute material as shown in FIG. 14. By such seed or wetting layer material deposited thereon coagulates with a high-contact angle as shown in FIG. 14 right-hand and reduces adhesion and thus reduces formation of closed voids inside the via. By applying such seed layer to the surface of the via, adhesion of subsequently deposited material is improved and complete filling of the via by the addressed material is improved.

As a material for such a seed or wetting layer, sputtered W or reactively sputtered Ta₂O₅ may be used, especially if the material to be deposited for filling the via is GST. Thereby, in a today preferred embodiment Ta₂O₅ is preferred as seed layer material since it has been shown to provide an excellent adhesion and it suppresses heat diffusion from GST material. A low heat transfer improves the performance of the phase transition device as is reported in Matsui et al. “Ta₂O₅ Interfacial Layer between GST and W Plug enabling Low Power Operation of Phase Change Memories”, Electron Devices Meeting, 2006. IEDM '06. International, vol. No., pp. 1, 4, 11-13, Dec. 2006, doi: 10.1109/IEDM.2006.346908.

The seed layer can be deposited in a separate vacuum processing chamber prior to introducing the resulting substrate with applied wetting layer to the one vacuum process chamber for sputter-deposition and ICP etching. Such seed layer is deposited with a thickness in the range of 0.5 nm to 5 nm (both limits included), depending on the quality of the via.

If a multi-source setup is used, i.e. with more than one sputtering target, an additional PVD source can be applied in the one common vacuum process chamber according to the invention so as to deposit the seed layer before material sputter-deposition is initiated. Such a multi-source layout is most schematically shown in FIG. 15 with an off-axis ICP source 80, sputter-sources 82 and 84 with respective targets, and a seed layer sputtering source 86. In such a setup of the processing chamber it is highly recommended to use shutters in combination with the addressed sources to prevent cross-contamination.

Just as examples repeating some aspects of the present invention:
ICP etching and sputter-deposition is performed in one and the same vacuum processing chamber.
The sputtering target arrangement and the substrate arrangement are mutually dimensioned so as to realize a medium-throw setup which improves low-angle material incidence upon the substrate.
An inductively coupled plasma—ICP—is generated in the vacuum process chamber via a dielectric, more specifically via a ceramic tube protected towards the inside of the processing chamber by a slotted shield.
In some embodiments a multi-source setup of the vacuum process chamber is realized with more than one target and with rotating single or multiple substrate. Rf is applied to the substrate during ICP etching. As shown in FIG. 15 the vacuum process chamber with multiple sources may be constructed for batch processing of multiple substrates being moved to be sequentially exposed to one source after the other.
Where necessary shutters may be provided to avoid cross-contamination, especially in multi-source setups.
For the etching process working at a low pressure Ar, Ne, Kr or Xe may be used as working gas. Processing cycles of material deposition/etching/material deposition may be repeated as required e.g. between 1 and 10 times.
The pressure for the sputter-deposition step is selected to be at least a factor 10 higher than the pressure for the ICP etching step.
The plasma of the sputter-deposition step is exploited to ignite the plasma for the etching step and vice versa.
A wetting or seed layer may be applied to the via in a separate processing chamber or in that chamber wherein sputter-deposition and etching is performed.
The ICT coil may be exploited also in the sputter-deposition step to control distribution of sputter-deposited material upon the substrate.

1. A method of material filling vias having an aspect ratio of at least approximately 1:1 within a substrate and thereby manufacturing substrates comprising vias filled with said material, said material being a chalcogenide glass material exhibiting a thermally driven amorphous/crystalline phase change out of the group of materials:
GeSbTe, AgInSbTe, InSe, SbSe, SbTe, InSbTe, GeSbSe, GeSbTeSe, AgInSbSeTe, thereby especially of GeSbTe (GST)
comprising:
step a):
sputter-depositing by DC sputtering said material from a target arrangement upon an area of at least one of said substrates comprising at least one via, thereby covering the via top, via sidewalls and via bottom of said via with a covering of said material and including a via top covering, said sputter depositing being performed to an extent to leave a void in said covered via, said void being open towards the surrounding of said via top covering;
subsequent to step a) a step b):
enlarging said void towards said surrounding by etching with the help of an inductively coupled plasma and Rf biased substrate;
subsequent to step b) a step c):
sputter-depositing said material by DC sputtering upon said area to an extent so as to
i) Completing a filling of said via by said material at least from said via bottom to said via top; or
ii) leaving a void in said covered via, said void being open towards the surrounding of said via top covering;
repeating in the case of ii) step b) and c),
thereby performing steps a) to c) in one common vacuum process chamber.

2. The method of claim 1 comprising performing said DC sputtering in said steps a) and c) without applying a bias signal to said substrate by a settable biasing source operationally connected to said substrate.

3. The method of claim 1, further comprising igniting said inductively coupled plasma by a plasma of said sputter depositing.

4. The method of claim 1, wherein said substrate is a silicon wafer.

5. The method of claim 1, further comprising:
providing said substrate in said one common vacuum process chamber along a substrate plane;
providing said target arrangement along a substantially plane or dome-shaped cover part of said one common vacuum process chamber, said target arrangement facing said substrate;
said cover part transiting into lateral walls of said common vacuum process chamber along a substantially circular area about a central axis and defining for an inner radius Rᵢ and an outer radius Rₐ, said circular area residing at least substantially in a transiting plane at least substantially parallel to said substrate plane;
selecting a spacing d between said substrate plane and said transiting plane with respect to said inner radius Rᵢ of said substantially circular area to be:
0.7≦Rᵢd≦1.6
preferably to be
1≦≦1.6.

6. The method of claim 1, thereby selecting total pressure in said common vacuum process chamber during step a) and during step c) to be higher than a total pressure selected in said one common vacuum process chamber during step b) by a factor of at least 2 to 30, preferably by a factor of at least 10.

7. The method of claim 1, comprising providing said target arrangement with more than one target.

8. The method of claim 7 comprising providing said more than one targets of different materials and controlling stoichiometry of said sputter-deposited material by controlling the sputtering rates of said more than one targets.

9. The method of claim 1, further comprising tilting at least one target of said target arrangement with respect to a substrate plane along which said at least one substrate resides.

10. The method of claim 1, comprising performing step b) at a total pressure p_{b} in said one common vacuum process chamber of
10⁻⁴ mbar≦p_{b}≦2·10⁻³ mbar
or of
10⁻⁴ mbar≦p_{b}≦10⁻³ mbar
Or of
5·10⁻⁴ mbar≦p_{b}≦2·10⁻³ mbar.

11. The method of one of claim 1, further comprising performing step a) and step c) at a total pressure pₐ, p_{c} in said common vacuum process chamber of
5·10⁻³ mbar≦pₐ≦5·10⁻² mbar,
5·10⁻³ mbar≦p_{c}≦5·10⁻² mbar,
or of
10⁻² mbar≦pₐ≦10⁻¹ mbar,
10⁻² mbar≦p_{c}≦10⁻¹ mbar.

12. The method of claim 1, further comprising generating said inductively coupled plasma by means of an electric coil arrangement with at least one electric coil wound around at least a part of the inner volume of said one common vacuum process chamber and preferably operating said coil with an electric current at a frequency fᵢ of:
400 kHz≦fᵢ≦27 MHz,
preferably of:
400 kHz≦fᵢ≦450 kHz.

13. The method of claim 1, further comprising generating said inductively coupled plasma by means of an electric coil arrangement with at least one electric coil wound around at least a part of the inner volume of said one common vacuum process chamber and operating said electric coil during at least one of steps a) and c) for controlling thickness distribution of said covering.

14. The method of claim 1, comprising applying said Rf biasing at a voltage u_{bias} of:
35 V≦u_{bias}≦100 V.

15. The method of claim 1, comprising applying before performing said step a) a seed layer in said via thereby preferably selecting thickness of said seed layer to be between 0.5 nm and 5 nm (both limits included).

16. The method of claim 15, comprising applying said seed layer of W or Ta₂O₅, thereby preferably applying W by sputtering and said Ta₂O₅ by reactive sputtering, preferably in combination with said material being GeSbTe.

17. The method of claim 15, further comprising applying said seed layer within said one common vacuum process chamber or in a separate vacuum process chamber.

18. The method of claim 1, further comprising rotating or oscillating said substrate during at least one of said steps a), b), c).

19. A substrate-via filling vacuum system comprising
a vacuum process chamber with at least one substrate holder therein;
said vacuum process chamber comprising
a sputtering target arrangement comprising one or more than one targets the material of the one target or the materials of the more than one targets in combination being of all elements of one material out of the group:
GeSbTe, AgInSbTe, InSe, SbSe, SbTe, InSbTe, GeSbSe, GeSbTeSe, AgInSbSeTe, thereby especially of GeSbTe (GST);
an electric coil arrangement with at least one electric coil wound around at least a part of the inner volume of said vacuum process chamber;
a first Rf power supply arrangement;
a second Rf power supply arrangement;
a continuous or pulsed DC power supply arrangement;
a process control unit;
said process control unit being adapted to control:
establishing of a supply operational connection of said DC power supply arrangement to said sputtering target arrangement for a first predetermined time span;
subsequent to said first time span, and for a second predetermined timespan:
disabling said supply operational supply connection of said DC power supply arrangement to said sputtering source arrangement; and
establishing of a supply operational connection of said first Rf power supply arrangement to said electric coil arrangement and establishing a bias operational connection of said second Rf Power Supply arrangement to said substrate holder.

20. The system of claim 19, wherein no signal supply source is operationally connected to said substrate holder during establishing said supply operational connection of said DC power supply arrangement.

21. The system of claim 19, wherein said process control unit controls said second time span to initiate as said first predetermined time span terminates.

22. The system of claim 19, said sputtering target arrangement comprising more than one target and said process control unit being adapted to individually control the sputter rate of said more than one targets.

23. The system of claim 22, at least some of said more than one targets being of different materials.

24. The system of claim 19, wherein said substrate holder defining a substrate plane within said vacuum process chamber, said vacuum process chamber comprising a substantially plane or dome-shaped cover part facing said substrate plane, said sputtering target arrangement being mounted along said cover part, said cover part transiting into lateral walls of said vacuum process chamber along a substantially circular area about a central axis and defining for an inner radius Rᵢ and an outer radius Rₐ with respect to said central axis, said circular area residing substantially in a transiting plane, at least substantially parallel to said substrate plane, wherein a spacing d between said substrate plane and said transiting plane with respect to said inner radius Rᵢ of said substantially circular area is:
0.7≦Rᵢ/d≦1.6
or
1≦Rᵢ/d≦1.6

25. The system of claim 19, wherein said process control unit is further adapted to control pressure in said vacuum process chamber during said second predetermined time span to be smaller than pressure in said vacuum process chamber during said first time span by a factor of at least 2 to 30, or by a factor of at least 10.

26. The system of claim 19, wherein said substrate holder defines for a substrate plane and the or at least one target of said sputtering target arrangement is tilted with respect to an axis perpendicular to said substrate plane by an angle of less than 90°.

27. The system of claim 19, wherein said electric coil arrangement comprises a tubular body of a di-electric material, preferably of a ceramic material, and at least one electric coil, the outer surface of said tubular body facing said at least one electric coil and the inner surface of said tubular body facing said part of said inner volume of said vacuum process chamber.

28. The system of claim 27, wherein said vacuum process chamber has an encapsulating wall and wherein said tubular body is a part of said encapsulating wall.

29. The system of claim 27 further comprises a slotted tubular shield along the inner surface of said tubular body, the slots thereof being preferably directed in a direction substantially parallel to a central axis of said tubular shield.

30. The system of claim 19, wherein said first Rf Power supply arrangement is adapted to generate Rf power at a frequency fᵢ of:
400 kHz≦fᵢ≦27 MHz,
or of:
400 kHz≦fᵢ≦450 kHz.

31. The system of claim 19, wherein said second Rf power supply arrangement is adapted to generate an Rf voltage u_{bias} of:
35V≦u_{bias}≦100V.

32. The system of claim 19, wherein said process control unit is adapted to maintain an operational connection of said electric coil arrangement to an Rf power supply arrangement during said first predetermined time span.

33. The system of claim 19, further comprising a sputtering source for a seed layer material preferably of W or of Ta₂O₅, said further sputtering source being provided within said vacuum process chamber or in a further process chamber remote from said vacuum process chamber.

34. The system of claim 19, wherein said process chamber is substantially symmetric to a central axis and said at least one electric coil is provided with a coil axis, which is coaxial to said central axis or which intersect said central axis.
